(19) United States
(12) Patent Application Publication
(10) Pub. No.: US 2011/0300686 A1
(43) Pub. Date: Dec. 8, 2011

(54) Methods of Fabricating Non-Volatile Memory Devices

(76) Inventors: Soo-doo Chae, Yongin-si (KR); Ki-hyun Hwang, Seongnam-si (KR); Han-mei Choi, Seoul (KR); Jun-kyu Yang, Seoul (KR); Byong-ju Kim, Suwon-si (KR)

(21) Appl. No.: 13/155,678

(22) Filed: Jun. 8, 2011

(30) Foreign Application Priority Data
Jun. 8, 2010 (KR) 10-2010-0053992

(51) Int. Cl. H01L 21/02

(52) U.S. Cl. 438/382; 257/E21.004

(57) ABSTRACT

Methods of forming non-volatile memory devices include forming a semiconductor layer having a first impurity region of first conductivity type extending adjacent a first side thereof and a second impurity region of second conductivity type extending adjacent a second side thereof, on a substrate. A first electrically conductive layer is also provided, which is electrically coupled to the first impurity region. The semiconductor layer is converted into a plurality of semiconductor diodes having respective first terminals electrically coupled to the first electrically conductive layer. The first electrically conductive layer operates as a word line or bit line of the non-volatile memory device. The converting may include patterning the first impurity region into a plurality of cathodes or anodes of the plurality of semiconductor diodes (e.g., P-i-N diodes).

### REFERENCE TO PRIORITY APPLICATION

This application claims the benefit of Korean Patent Application No. 10-2010-0053992, filed Jun. 8, 2010, in the Korean Intellectual Property Office, the disclosure of which is hereby incorporated herein in its entirety by reference.

### BACKGROUND

The inventive concept relates to methods of fabricating memory devices and, more particularly, to methods of fabricating non-volatile memory devices.

Development of the semiconductor industry and user demand lead to highly integrated and high performance electronic devices. Correspondingly, demand for highly integrated and high performance semiconductor devices, which are a key component of electronic devices, are also increasing. However, conventional memory devices are inappropriate for high degrees of integration of a semiconductor device.

### SUMMARY

Methods of forming non-volatile memory devices according to embodiments of the invention include forming a semiconductor layer on a substrate. The semiconductor layer has a first impurity region of first conductivity type extending adjacent a first side thereof and a second impurity region of second conductivity type extending adjacent a second side thereof. A first electrically conductive layer is also provided, which is electrically coupled to the first impurity region. The semiconductor layer is converted into a plurality of semiconductor diodes having respective first terminals (e.g., cathode/anode terminals) electrically coupled to the first electrically conductive layer. According to some embodiments of the invention, the first electrically conductive layer operates as a word line or bit line of the non-volatile memory device. In addition, the converting may include patterning the first impurity region into a plurality of cathodes or anodes of the plurality of semiconductor diodes (e.g., P-i-N diodes).

According to additional embodiments of the invention, the non-volatile memory device includes memory cells having variable resistance data storage regions therein. In these embodiments, the step of forming a first electrically conductive layer may be preceded by forming a variable resistance material on the first impurity region so that the variable resistance material is sandwiched between the first impurity region and the first electrically conductive layer.

According to still further embodiments of the invention, a method of forming a non-volatile memory device may include selectively implanting first conductivity type dopants into a semiconductor layer to thereby define a first impurity region therein having N-type or P-type conductivity. This first impurity region is selectively etched to define a sidewall thereon and then a first word line or a first bit line is formed on the sidewall of the first impurity region. The semiconductor layer is also converted into a plurality of memory cells containing respective portions of the first impurity region therein. This converting may include selectively patterning the semiconductor layer into a plurality of memory cell active regions and incorporating second conductivity type dopants into each of the plurality of memory cell active regions to thereby define respective second impurity regions therein. In particular, the incorporating may include incorporating second conductivity type dopants into a first of the plurality of memory cell active regions to thereby define a P-i-N diode therein. A step may also be performed to form a second word line or second bit line on a corresponding first one of the second impurity regions. In the event the non-volatile memory device is a variable resistance memory device, a step may be performed to form a variable-resistance material that is sandwiched between the second word line (or second bit line) and the first one of the second impurity regions.

### BRIEF DESCRIPTION OF THE DRAWINGS

Exemplary embodiments of the inventive concept will be more clearly understood from the following detailed description taken in conjunction with the accompanying drawings in which:

FIGS. 1A through 1H are sectional views for explaining a process of forming a horizontal device layer in a method of manufacturing a non-volatile memory device according to an embodiment of the inventive concept;

FIG. 2 is a sectional view of a stack structure formed according to an embodiment of the inventive concept;

FIGS. 3A through 3C are sectional views for explaining a process of forming a second impurity region, according to an embodiment of the inventive concept;

FIGS. 4A and 4B are sectional views for explaining a process of forming a variable resistance material layer, according to an embodiment of the inventive concept;

FIGS. 5A through 5C are sectional views and a plan view for explaining an aspect of a process of forming a vertical conductive layer, according to an embodiment of the inventive concept;

FIGS. 6A through 6E are sectional views and plan views for explaining another aspect of a process of forming a vertical conductive layer, according to an embodiment of the inventive concept;

FIG. 7 is a schematic block diagram of a non-volatile memory device according to embodiment of the inventive concept;

FIG. 8 is a schematic diagram of a memory card according to an embodiment of the inventive concept; and

FIG. 9 is a block diagram of an electronic system according to an embodiment of the inventive concept.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. Furthermore, in the accompanying drawings, various elements and regions are schematically drawn. Accordingly, the inventive concept is not limited to the relative sizes or intervals drawn in the accompanying drawings.

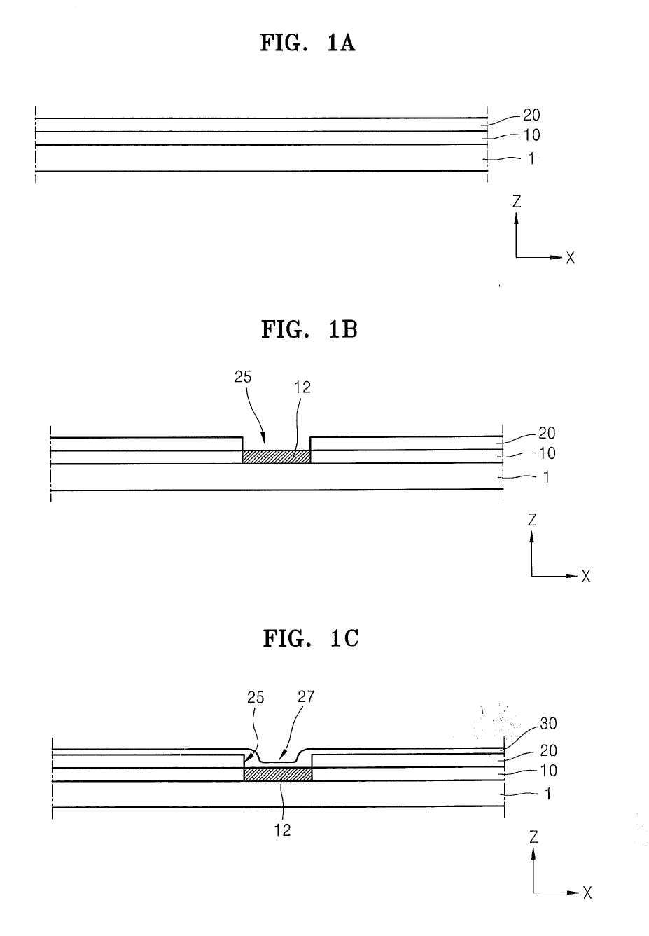

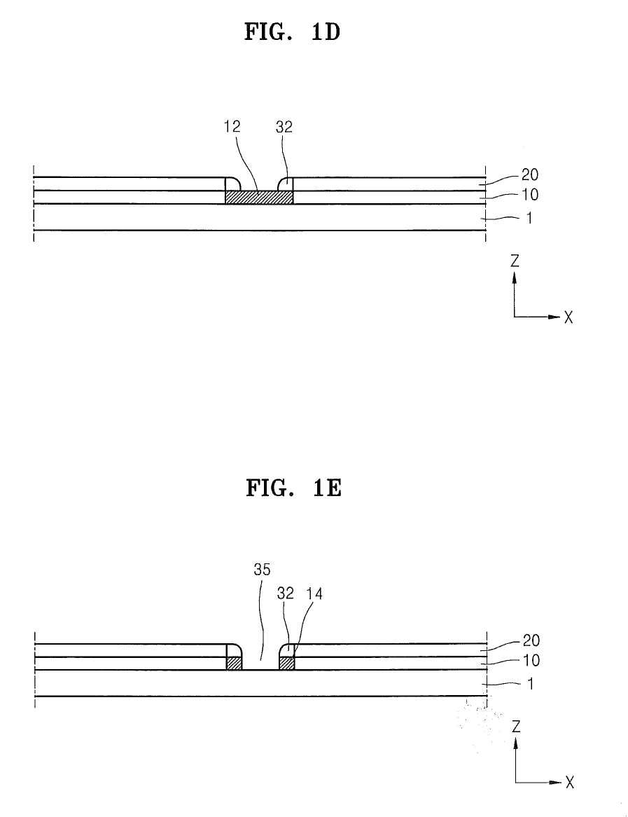

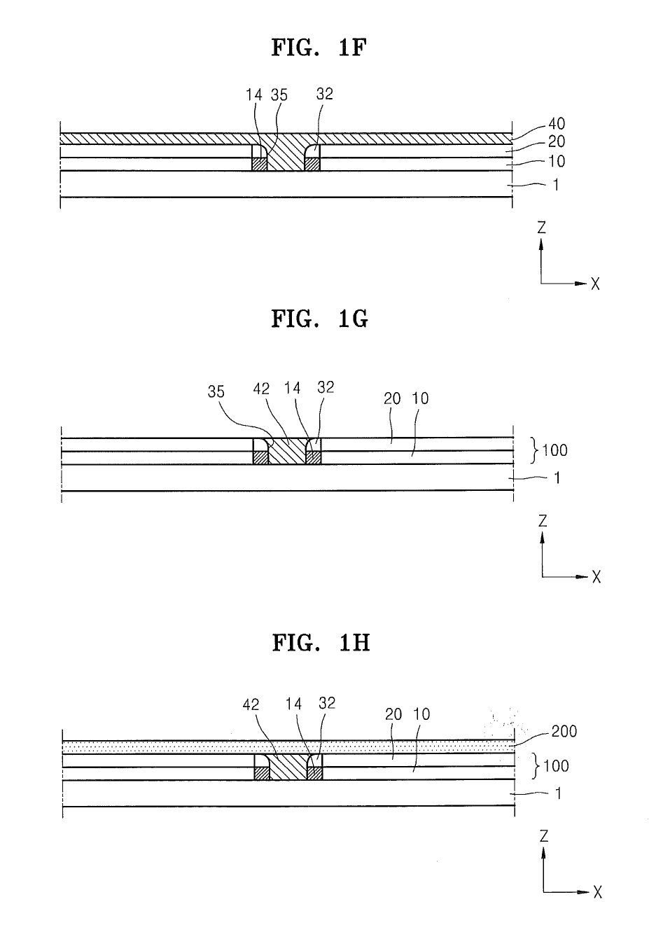

FIGS. 1A through 111 are sectional views for explaining a process of forming a horizontal device layer in a method of manufacturing a non-volatile memory device according to an embodiment of the inventive concept. FIG. 1A is a sectional view for explaining a process of forming a semiconductor layer 10 and a cover insulating layer 20, according to an embodiment of the inventive concept. Referring to FIG. 1A, the semiconductor layer 10 and the cover insulating layer 20 are formed on a substrate 1. The substrate 1 may be a semiconductor substrate such as a silicon or compound semiconductor wafer. Alternatively, the substrate 1 may instead be a glass, metal, ceramic, or quartz substrate. A field oxide layer or an insulating layer, which is formed of an insulating material, may be formed between the substrate 1 and the semiconductor layer 10. The semiconductor layer 10 may include a mono semiconductor layer or a compound semiconductor layer, which is formed of silicon (Si), germanium (Ge), GaAs, or GaN. The semiconductor layer 10 may be a single crystal, polycrystal, or amorphous layer. The semiconductor layer 10 may include, for example, polysilicon. The semiconductor layer 10 may have a thickness of about 50 Å through 600 Å. The semiconductor layer 10 may be formed by sputtering or chemical vapor deposition (CVD).

The cover insulating layer 20 may be formed on the semiconductor layer 10. The cover insulating layer 20 may be a silicon oxidation layer, a silicon nitride layer, or a silicon nitride layer or an insulating layer with a high dielectric constant, such as a tantalum oxidation layer or an aluminum oxidation layer. Alternatively, the cover insulating layer 20 may be an insulating layer formed of an organic material. The cover insulating layer 10 may have a thickness of about 30 Å through 400 Å. The cover insulating layer 20 may be formed by sputtering or CVD.

FIG. 1B is a sectional view for explaining a process of forming an opening 25 and a preliminary first impurity region 12, according to an embodiment of the inventive concept. Referring to FIG. 1B, the opening 25 exposing the semiconductor layer 10 may be formed in the cover insulating layer 20. The opening 25 may be formed by, for example, photolithography and etching. The opening 25 may have a line form having a width of about 500 Å through 2000 Å.

Subsequently, an impurity having a first conductivity type is implanted in a portion of the semiconductor layer 10 through the opening 25, thereby forming the preliminary first impurity region 12 having the first conductivity type. The implantation of the impurity having the first conductivity type in the preliminary first impurity region 12 may be performed by ion implantation, plasma doping (PLAD), irradiation of a gas cluster ion beam (GCIB), or phosphorus diffusion using POCl₃. The preliminary first impurity region 12 may be formed in an n+type state by using, for example, an n-type impurity such as phosphorous or arsenic. Alternatively, selectively, the preliminary first impurity region 12 may be formed in a p+type state by using, for example, a p-type impurity.

FIG. 1C is a sectional view for explaining a process of forming a preliminary spacer layer 30, according to an embodiment of the inventive concept. Referring to FIG. 1C, the preliminary spacer layer 30 is formed on the cover insulating layer 20 and the preliminary first impurity region 12. The preliminary spacer layer 30 may cover an upper surface of the cover insulating layer 20, a side surface (e.g., sidewall) of the cover insulating layer 20 exposed by the opening 25, and an upper surface of the preliminary first impurity region 12. In this regard, the preliminary spacer layer 30 may have a smaller thickness than the cover insulating layer 20 so as to form a recess region 27 in the opening 25. The thickness of the preliminary spacer layer 30 may determine a size, that is, a junction thickness of a first impurity region which will be formed later. The preliminary spacer layer 30 may be formed of an insulating material. The preliminary spacer layer 30 may be formed of, for example, a nitride or oxide. The preliminary spacer layer 30 may be formed of a material with etch selectivity with respect to the cover insulating layer 20. For example, when the cover insulating layer 20 is formed of an oxide, the preliminary spacer layer 30 is formed of a nitride.

FIG. 1D is a sectional view for explaining a process of forming a spacer layer 32, according to an embodiment of the inventive concept. Referring to FIG. 1D, the preliminary spacer layer 30 illustrated in FIG. 1C is anisotropic-etched to expose a portion of the upper surface of the preliminary first impurity region 12 and an upper surface of the cover insulating layer 20, thereby forming the spacer layer 32. The spacer layer 32 may be formed covering the portion of the upper surface of the preliminary first impurity region 12 and the side surface of the cover insulating layer 20 exposed by the opening 25.

FIG. 1E is a sectional view for explaining a process of forming a first impurity region 14 according to an embodiment of the inventive concept. Referring to FIG. 1E, a portion of the preliminary first impurity region 12 is removed to form the first impurity region 14 and a trench 35 passing through the preliminary first impurity region 12 illustrated in FIG. 1D. The first impurity region 14 may be formed by anisotropic etching the preliminary first impurity region 12 using the cover insulating layer 20 and the spacer layer 32 as etch masks. The trench 35 may have a line form.

Accordingly, the spacer layer 32 may cover an upper surface of the first impurity region 14, and the cover insulating layer 20 may cover an upper surface of a portion of the semiconductor layer 10 other than the first impurity region 14. Accordingly, in a first direction (a positive X direction or negative X direction) parallel to a surface of the substrate 1, the first impurity region 14 may be defined to have substantially the same width (thickness) as a width of the spacer layer 32 (that is, a thickness of the preliminary spacer layer 30 illustrated in FIG. 1C). Thus, the semiconductor layer 10 may include the first impurity region 14 on its one side in the first direction (the positive X direction or negative X direction) parallel to a surface of the substrate 1. Since the first impurity region 14 is a part of the semiconductor layer 10, upper surfaces of the first impurity region 14 and the semiconductor layer 10 may lie on the same plane as each other and lower surfaces of the first impurity region 14 and the semiconductor layer 10 may also lie on the same plane as each other. The trench 35 may be a space having a line form extending in a second direction perpendicular to the first direction (the positive X direction or negative X direction) parallel to a surface of the substrate 1. Correspondingly, the opening 25 illustrated in FIG. 1B may also have a line form extending in the second direction. The second direction may be a Y direction which will be described later. After the first impurity region 14 is formed, a variable resistance material may be selectively deposited on the first impurity region 14. This process will be described later in detail.

FIG. 1F is a sectional view for explaining a process of forming a conductive material layer 40, according to an embodiment of the inventive concept. Referring to FIG. 1F, the conductive material layer 40 is formed on substrate 1 to completely fill the trench 35. The conductive material layer 40 may be, for example, a metal, polysilicon or conductive oxide, or nitride. The conductive material layer 40 may have a lower portion including a barrier layer contacting a side surface of the trench 35. The conductive material layer 40 may include, for example, tungsten and the barrier layer formed of Ti/TiN. The conductive material layer 40 may be formed by sputtering or CVD.

FIG. 1G is a sectional view for explaining a process of forming a horizontal conductive layer 40, according to an embodiment of the inventive concept. Referring to FIG. 1 G, the conductive material layer 40 illustrated in FIG. 1G is planarized by removing a portion of the conductive material layer 40 such that the conductive material layer 40 remains only in the trench 35, thereby forming the horizontal conductive layer 42. The horizontal conductive layer 42 may be formed by etching back or performing chemical mechanical polishing (CMP) on the conductive material layer 40 using the cover insulating layer 20 as an etch stopper. If the trench 35 has a line form, the horizontal conductive layer 42 may correspondingly have a line form. The horizontal conductive layer 42 may extend along the trench 35 in the second direction (a direction perpendicular to an X axis and a Z axis) parallel to the surface of the substrate 1. In addition, the horizontal conductive layer 42 contacts the first impurity region 14 included in the semiconductor layer 10 and may be electrically connected to the first impurity region 14. Hereinafter, the structure including the semiconductor layer 10 including the first impurity region 14, the cover insulating layer 20, the spacer layer 32, and the horizontal conductive layer 42 will be referred to as an horizontal device layer 100. The horizontal device layer 100 may be used later to form semiconductor diodes lying in the same level.

FIG. 1H is a sectional view for explaining a process of forming an interlayer insulating layer 200, according to an embodiment of the inventive concept. Referring to FIG. 1H, the interlayer insulating layer 200 is formed covering the horizontal device layer 100. The interlayer insulating layer 200 may include a silicon oxidation layer, a silicon nitride layer, or a layer formed of other insulating materials. When an additional horizontal device layer 100 is formed in a third direction (a Z direction) parallel to the surface of the substrate 1, the interlayer insulating layer 200 may electrically insulate neighboring horizontal device layers 100 from each other.

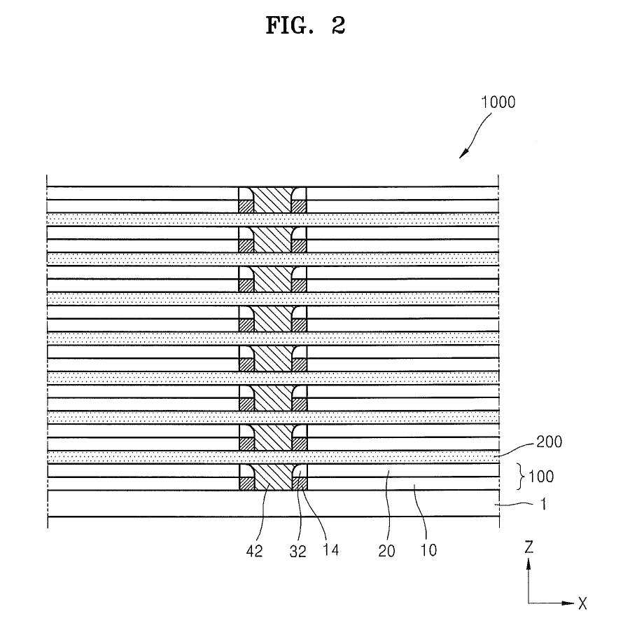

FIG. 2 is a sectional view of a stack structure 1000 formed according to an embodiment of the inventive concept. Referring to FIG. 2, the stack structure 1000 includes a plurality of the horizontal device layers 100 described in connection with FIGS. 1A through 1G and a plurality of the interlayer insulating layers 200 described in connection with FIG. 1H, wherein the horizontal device layers 100 and the interlayer insulating layers 200 are alternately deposited such that the interlayer insulating layer 200 is interposed between neighboring horizontal device layers 100. That is, as explained in connection with FIGS. 1A through 111, the horizontal device layer 100 and the interlayer insulating layer 200 are formed and then the same processes are repeatedly performed.

In FIG. 2, eight horizontal device layers 100 and seven interlayer insulating layers 200 interposed between the horizontal device layers 100 are illustrated, but the inventive concept is not limited thereto. For example, two, four, eight, or more than eight horizontal device layers 100 may be spaced apart from each other and may lie at different heights, that is, at different levels, in the third direction (the Z direction) parallel to the surface of the substrate 1, wherein the interlayer insulating layer 200 may be disposed between neighboring horizontal device layers 100.

The number of the horizontal device layers 100 may be determined in consideration of the size or storage capacity of a non-volatile memory device to be fabricated.

Although not illustrated, the stack structure 1000 may further include an insulating layer covering the upper most horizontal device layer 100, which acts as a passivation layer. Although not illustrated, a plurality of the stack structures 1000 may be repeatedly connected in the first direction (the positive X direction or negative X direction).

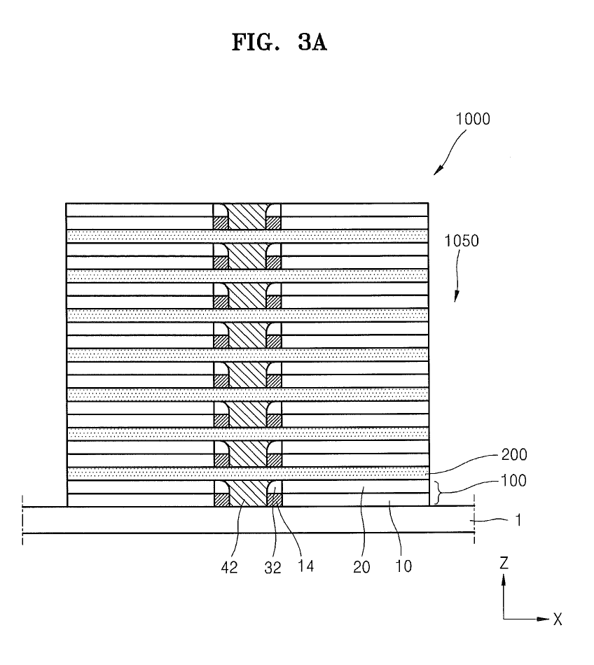

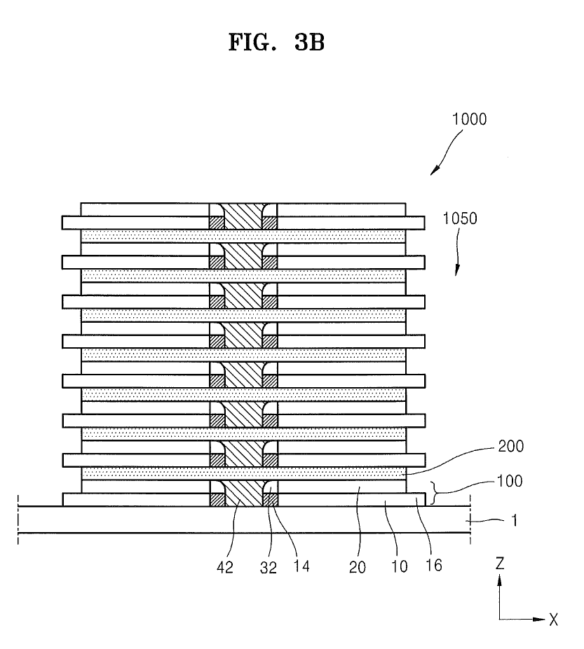

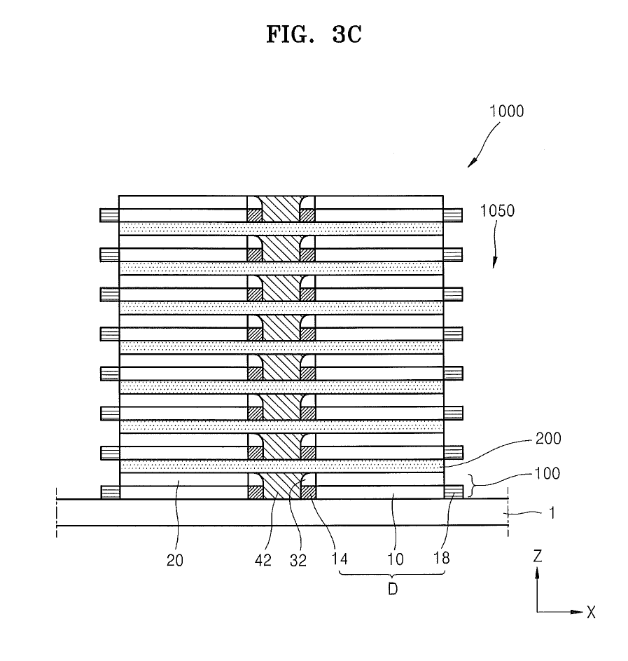

FIGS. 3A through 3C are sectional views for explaining a process of forming a second impurity region, according to an embodiment of the inventive concept. FIG. 3A is a sectional view for explaining a process of removing a side portion of the stack structure 1000, according to an embodiment of the inventive concept. Referring to FIG. 3A, a portion of the stack structure 1000 is removed to expose the substrate 1, thereby exposing the other side of the semiconductor layer 10 opposite to the one side of the semiconductor layer 10 on which the first impurity region 14 is present. That is, the first impurity region 14 is present on the one side of the semiconductor layer 10 in the first direction (the positive X direction or negative X direction) parallel to the surface of the substrate 1 and the other side of the semiconductor layer 10 opposite thereto in a direction (the negative X direction or positive X direction) opposite to the first direction may be exposed. The portion of the stack structure 1000 may be removed by photolithography and etching, thereby forming a separation space 1050. When a plurality of the stack structures 1000 illustrated in FIG. 2 are repeatedly connected, the separation space 1050 may separate neighboring stack structures 1000 from each other.

FIG. 3B is a sectional view for explaining a process of protruding a portion of the exposed side of the semiconductor layer, according to an embodiment of the inventive concept. Referring to FIG. 3B, portions of the cover insulating layer 20 and the interlayer insulating layer 200 that are adjacent to their respective exposed sides are removed through the separation space 1050, thereby protruding a portion of the semiconductor layer 10 with respect to the cover insulating layer 20 and the interlayer insulating layer 200. Hereinafter, the protrusion of the semiconductor layer 10 will be referred to as a protrusion 16. That is, the protrusion 16 and the first impurity region 14 may be located in opposite directions in the semiconductor layer 10. That is, the first impurity region 14 may be located on the one side of the semiconductor layer 10 in the first direction (the positive X direction or negative X direction) parallel to the surface of the substrate 1, and the protrusion 16 may be located on the other side of the semiconductor layer 10 in a direction (the negative X direction or positive X direction) opposite to the first direction.

In order to form the protrusion 16, although not shown, a mask layer partially covering an upper surface of the stack structure 1000 may be used. The mask layer may be separately formed. Alternatively, the mask layer may instead be residual photoresist remaining after a photolithography process for forming the separation space 1050 is performed. In order to form the protrusion 16, an isotropic etch process may be used in which the semiconductor layer 10 has an etch selectivity with respect to the cover insulating layer 20 and the interlayer insulating layer 200. Optionally, the process of forming the protrusion 16 may not be used.

FIG. 3C is a sectional view for explaining a process of forming a second impurity region 18, according to an embodiment of the inventive concept. Referring to FIG. 3C, an impurity having a second conductivity type that is different from the first conductivity type described above is implanted in the protrusion 16 illustrated in FIG. 3B, thereby forming the second impurity region 18 having the second conductivity type. The implantation of the impurity having a second conductivity type to form the second impurity region 18 may be performed by ion implantation, plasma doping (PLAD), irradiation of a gas cluster ion beam (GCIB), or phosphorus diffusion using POCl₃. If the effect of diffusion is ignored, the second impurity region 18 may be formed substantially in the protrusion 16. Accordingly, by controlling portions of the cover insulating layer 20 and the interlayer insulating layer 200, which are removed to form the protrusion 16, the size, that is, junction thickness, of the second impurity region 18 may be defined. The second impurity region 18 may be formed in a p+type state by using, for example, a p-type impurity such as boron. Alternatively, selectively, the second impurity region 18 may be formed in an n+type state by using, for example, an n-type impurity. If the first impurity region 14 is n-type, the second impurity region 18 may be p-type. On the other hand, if the first impurity region 14 is p-type, the second impurity region 18 may be n-type. Accordingly, the semiconductor layer 10 may have a p-i-n (p-type/intrinsic/n-type) structure. If the second impurity region 18 is formed in the whole of the semiconductor layer 10 except than the first impurity region 14, the semiconductor layer may have a pn structure.

As described above, when the protrusion 16 is not formed, an impurity is implanted in the side surface of semiconductor layer 10 through the separation space 1050 to form the second impurity region 18. In this case, the second impurity region 18 may be formed by ion-implanting the impurity having a second conductivity type at an angle with respect to the third direction (the Z direction) perpendicular to the surface of the substrate 1.

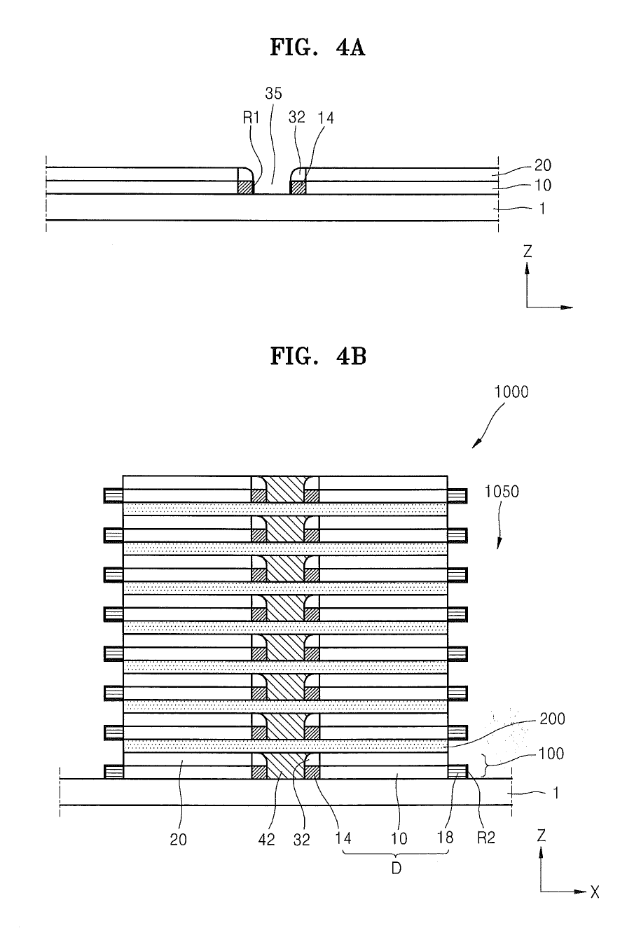

FIGS. 4A and 4B are sectional views for explaining a process of forming a variable resistance material layer, according to an embodiment of the inventive concept. FIG. 4A is a sectional view for explaining an aspect of a process of forming a variable resistance material layer according to an embodiment of the inventive concept. The process illustrated in FIG. 4A may be selectively performed between the process illustrated in FIG. 1E and the process illustrated in FIG. 1F. Referring to FIGS. 1E and 4A, a first variable resistance material layer R1 may be deposited on the side surface of the first impurity region 14 exposed by the trench 35. The first variable resistance material layer R1 may be formed by oxidizing the side surface of the first impurity region 14 in an appropriate oxidizing ambient. Alternatively, the first variable resistance material layer R1 may be deposited on both a side surface of the cover insulating layer 20 and the side surface of the first impurity region 14. Then, an anisotropic etch process is selectively performed such that the first variable resistance material layer R1 remains only on the first impurity region 14. The first variable resistance material layer R1 may include a material with a variable resistance that has a relatively low or high resistance by application of an appropriate electric pulse. As used herein, the term “variable resistance material” means any material capable of exhibiting more than one value of electrical resistivity, and hence, conductivity.

FIG. 4B is a sectional view for explaining another aspect of a process of forming a variable resistance material layer according to an embodiment of the inventive concept. The process illustrated in FIG. 4B is selectively used after the process illustrated in FIG. 3C. Referring to FIG. 4B, a second variable resistance material layer R2 may be deposited on the exposed surface of the second impurity region 18. When the protrusion 16 illustrated in FIG. 3B is formed, the second variable resistance material layer R2 may be formed surrounding the protrusion 16. The second variable resistance material layer R2 may be formed by oxidizing the side surface of the second impurity region 18 in an appropriate oxidizing ambient. Alternatively, the second variable resistance material layer R2 may be deposited on surfaces of the cover insulating layer 20, the interlayer insulating layer 200, and the second impurity region 18. The second variable resistance material layer R2 may include a material with a variable resistance that has a relatively low or high resistance by application of an appropriate electric pulse. Only one of the first variable resistance material layer R1 illustrated in FIG. 4A and the second variable resistance material layer R2 illustrated in FIG. 4B may be selectively formed.

As described above, since only one of the first variable resistance material layer R1 and the second variable resistance material layer R2 is selectively formed, they are not illustrated in the drawings illustrating the subsequent processes. That is, if the first variable resistance material layer R1 is formed, the first variable resistance material layer R1 may be present in FIGS. 1F through 3C, and FIGS. 5A through SC and 6A through 6E which will be referred to later. On the other hand, if the second variable resistance material layer R2 is formed, the second variable resistance material layer R2 may be present in FIGS. SA through SC and 6A through 6E which will be referred to later.

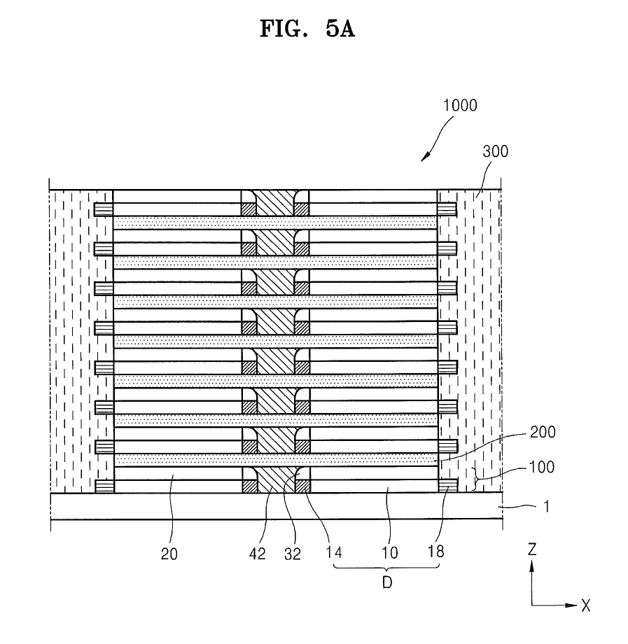

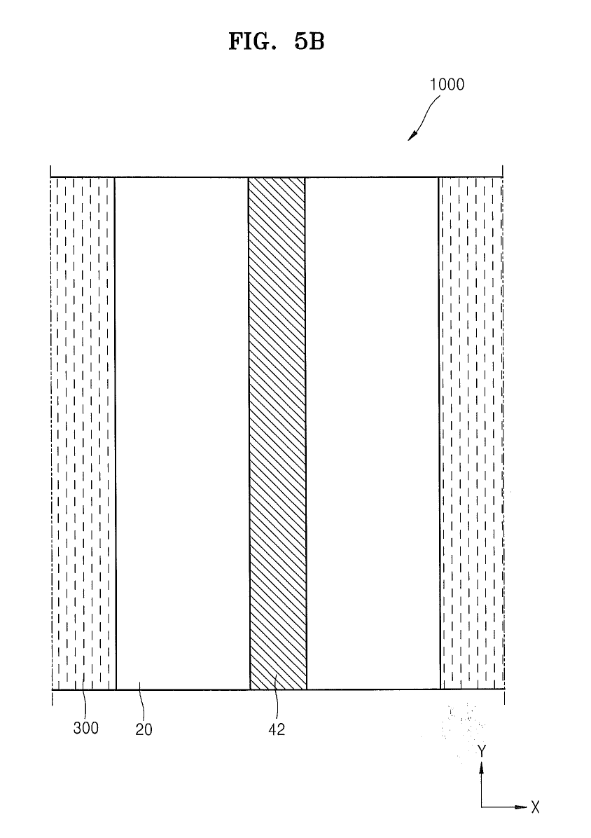

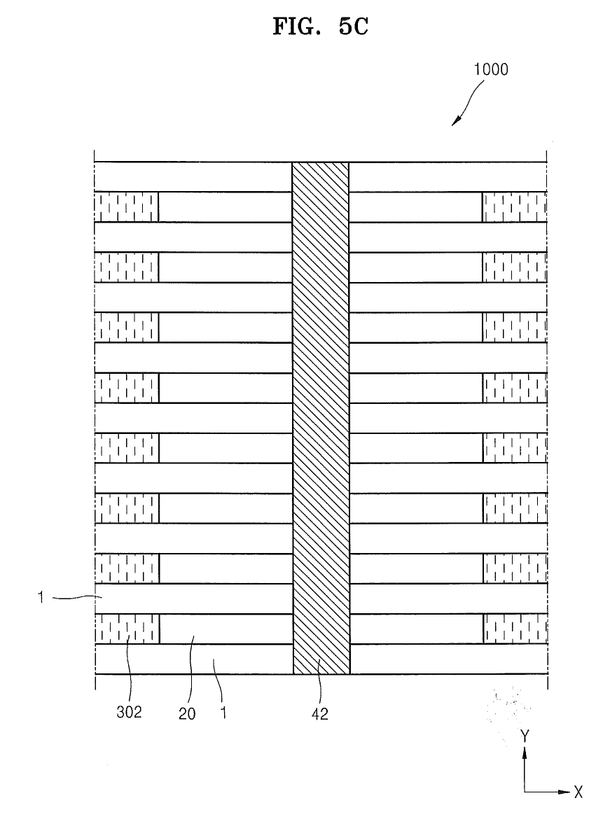

FIGS. 5A through 5C are sectional views and a plan view for explaining an aspect of a process of forming a vertical conductive layer, according to an embodiment of the inventive concept. FIG. 5A is a sectional view for explaining a process of forming a vertical filler conductive layer 300, according to an embodiment of the inventive concept. Referring to FIG. 5A, the vertical filler conductive layer 300 is formed to surround the exposed surface of the second impurity region 18 and fill the separation space 1050. When the protrusion 16 illustrated in FIG. 3B is formed, the vertical filler conductive layer 300 may be formed to surround the protrusion 16. The vertical filler conductive layer 300 may be formed by depositing a conductive material to entirely cover the stack structure 1000 and then etching back or performing CMP on the resultant structure by using the stack structure 1000 as an etch stopper.

The vertical filler conductive layer 300 may include, for example, metal, polysilicon or a conductive oxide or nitride. In addition, the vertical filler conductive layer 300 may include a barrier layer contacting the second impurity region 18. The vertical filler conductive layer 300 may include, for example, tungsten and a barrier layer formed of Ti/TiN.

The vertical filler conductive layer 300 may be formed by sputtering or CVD. Later, the vertical filler conductive layer 300 and the stack structure 1000 are separately or simultaneously divided into pluralities such that the respective cut portions extend in a direction from the first impurity region 14 and the second impurity region 18 of the semiconductor layer 10, thereby forming a three-dimensional array of semiconductor diodes D. This process will now be described in connection with FIGS. 5B through 5C. Each of the semiconductor diodes D may include a portion of the first impurity region 14 and a portion of the second impurity region 18. FIG. 5B is a plan view for explaining a process of forming a vertical filler conductive layer, according to an embodiment of the inventive concept. In detail, FIG. 5B is a plan view of the structure illustrated in FIG. 5A.

Referring to FIG. 5A and FIG. 5B, the vertical filler conductive layer 300 is formed on at least a side of the stack structure 1000. The horizontal conductive layer 42 may extend. in the second direction Y that is perpendicular to the first direction (the positive X direction or negative X direction), which is a direction in which the first impurity region 14 and the second impurity region 18 of the semiconductor layer 10 are connected to each other, and that is parallel to the surface of the substrate 1.

Although not shown, the horizontal conductive layer 42 included in the horizontal device layer 100 that is relatively closer to the substrate 1 may extend farther than the horizontal conductive layer 42 included in the horizontal device layer 100 that is relatively farther away from the substrate 1. In this case, the horizontal conductive layers 42 may have a step-like structure, and by using the structure of the horizontal conductive layers 42, a contact plug for connection to the outside may be formed.

The horizontal conductive layer 42 is formed on one side of the semiconductor layer 10, that is, a side of the semiconductor layer 10 on which the first impurity region 14 is formed, and the vertical filler conductive layer 300 is formed on the other side opposite to the one side of the semiconductor layer 10, that is, a side of the semiconductor layer 10 on which the second impurity region 16 is formed.

FIG. 5C is a plan view for explaining a process of forming semiconductor diodes, according to an embodiment of the inventive concept. Referring to FIG. 5A through FIG. 5C, the cover insulating layer 20, the interlayer insulating layer 200, the semiconductor layer 10, and the vertical filler conductive layer 300 are divided into pluralities along an extending line passing through the sides of the semiconductor layer 10, thereby forming a three-dimensional array of semiconductor diodes D. Each separated part of the semiconductor layer 10 corresponds to a semiconductor diode D, and each separated part of the vertical filler conductive layer 300 will be referred to as a vertical conductive layer 302. Each of vertical conductive layers 302 may contact the second impurity regions 18 of the semiconductor diodes D along the third direction Z perpendicular to the surface of the substrate 1 and may electrically connect the second impurity regions 18 to each other. That is, the vertical conductive layers 302 extend in the third direction Z on the substrate 1 and are electrically connected to the portions of the second impurity region 18 included in each of the semiconductor diodes D aligned in the third direction Z in the three-dimensional array of semiconductor diodes D, respectively. Accordingly, the vertical conductive layer 302 may function as a bit line in the three-dimensional array of semiconductor diodes D. When the protrusion 16 illustrated in FIG. 3B is formed, the vertical conductive layer 302 may be formed surrounding the protrusion 16. The horizontal conductive layer 42 may electrically connect the first impurity regions 14 of semiconductor diodes D along the second direction Y parallel to the surface of the substrate 1. Accordingly, the horizontal conductive layer 42 may function as a word line in the three-dimensional array of semiconductor diodes D. Alternatively, selectively, the vertical conductive layer 302 and the horizontal conductive layer 42 may function as a word line and a bit line, respectively.

When the first variable resistance material layer R1 illustrated in FIG. 1F is formed between the first impurity region 14 of the semiconductor diode D and the horizontal conductive layer 42, or the second variable resistance material layer R2 illustrated in FIG. 3D is formed between the second impurity region 18 of the semiconductor diode D and the vertical conductive layer 302, the three-dimensional array of the semiconductor diode D may embody a three-dimensional array of a resistive memory RAM (RRAM). Accordingly, a non-volatile memory device may be embodied.

As illustrated in FIG. 3C, when the second impurity region 18 is formed in the protrusion 16, a contact area between the vertical conductive layer 302 and the second impurity region 18 of the semiconductor diode D is increased and thus, a contact resistance may be reduced. Accordingly, performance of a resistive memory cell may be further enhanced.

The division of the cover insulating layer 20, the semiconductor layer 10, and the vertical filler conductive layer 300 may be performed by photolithography and etching The division of the cover insulating layer 20 and the semiconductor layer 10 and the division of the vertical filler conductive layer 300 may be performed simultaneously or separately.

In order to divide the cover insulating layer 20, the semiconductor layer 10, and the vertical filler conductive layer 300, portions of the cover insulating layer 20, the semiconductor layer 10, and the vertical filler conductive layer 300 are removed to expose the substrate 1. In the subsequent process, a filling insulating layer (not shown) may be formed in the empty space formed from which the portions of the cover insulating layer 20, the semiconductor layer 10, and the vertical filler conductive layer 300 are removed.

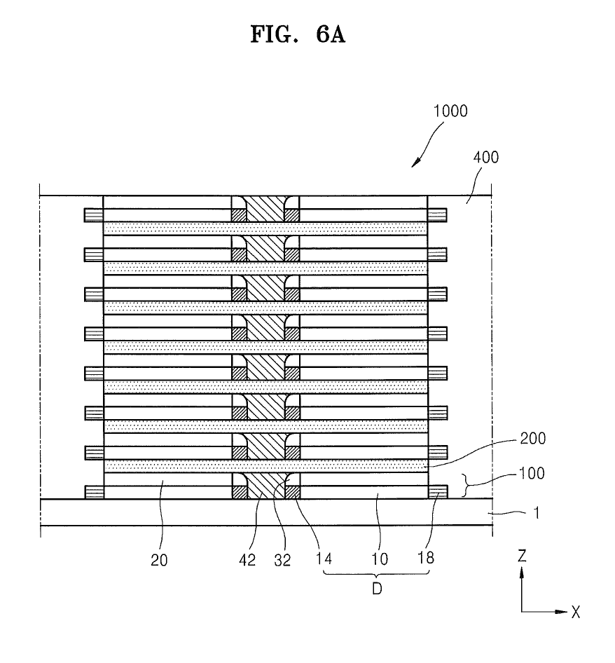

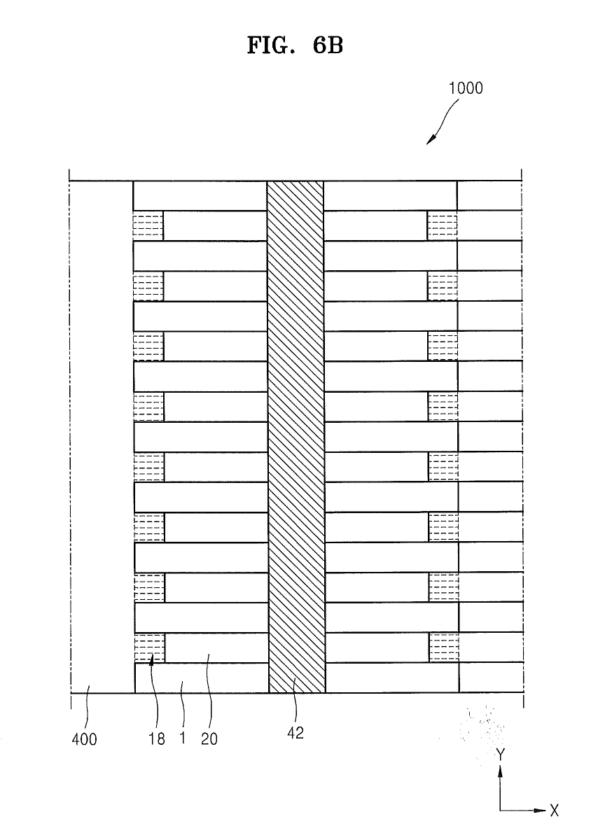

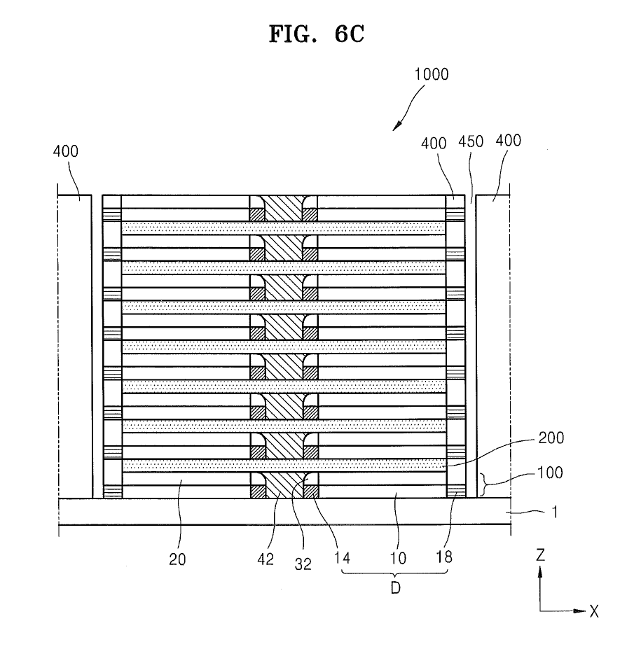

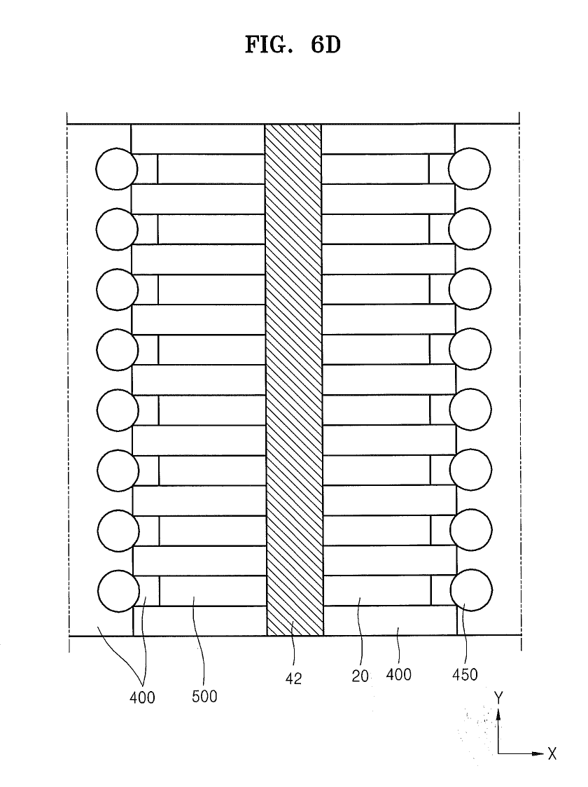

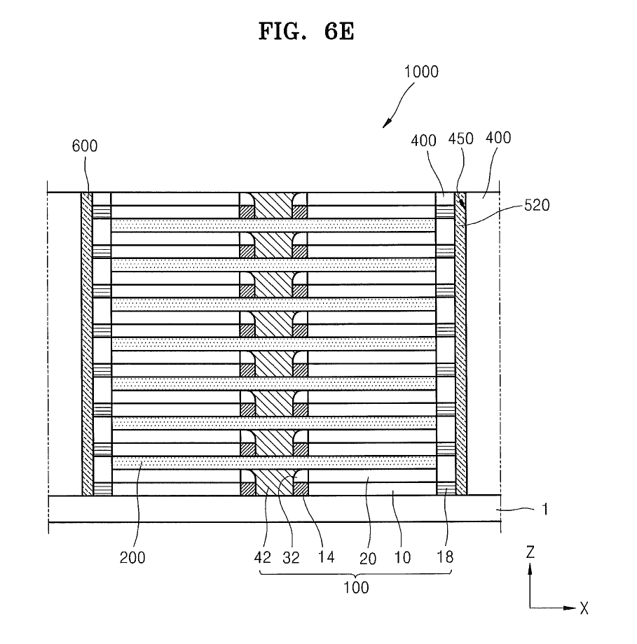

FIGS. 6A through 6E are sectional views and plan views for explaining another aspect of a process of forming a vertical conductive layer, according to an embodiment of the inventive concept. Referring to FIG. 6A, a first filling insulating layer 400 is formed to completely fill the separation space 1050 illustrated in FIG. 3C. The first filling insulating layer 400 may be formed using the same method as used to form the vertical filler conductive layer 300 illustrated in FIG. 5A, except that the vertical filler conductive layer 300 is formed of a conductive material and the first filling insulating layer 400 is formed of an insulating material. An upper surface of the first filling insulating layer 400 and the upper surface of the stack structure 1000 may lie on the same plane, or an upper surface of the first filling insulating layer 400 may be positioned higher than the upper surface of the stack structure 1000. The first filling insulating layer 400 may be a silicon oxidation layer, a silicon nitride layer, an organic insulating material layer, or a layer formed of other insulating oxides or an insulating nitride.

FIG. 6B are a plan view of a process of forming semiconductor diodes, according to an embodiment of the inventive concept. Referring to FIGS. 6A and 6B, the cover insulating layer 20, the interlayer insulating layer 200, and the semiconductor layer 10 are divided into pluralities by cutting the cover insulating layer 20, the interlayer insulating layer 200, and the semiconductor layer 10 in such a way that the respective cut portions extend in a direction from the one side of the semiconductor layer 10 to the other side of the semiconductor layer 10, thereby forming a three-dimensional array of semiconductor diodes D.

The division of the cover insulating layer 20, the interlayer insulating layer 200, and the semiconductor layer 10 may be performed by photolithography and etching. In order to divide the cover insulating layer 20, the interlayer insulating layer 200, and the semiconductor layer 10, portions of the cover insulating layer 20, the interlayer insulating layer 200, and the semiconductor layer 10 are removed to expose the substrate 1. In this case, portions of the first filling insulating layer 400 disposed on and under the second impurity region 18 may also be removed.

FIGS. 6C and 6D are a sectional view and a plan view for explaining a process of forming a vertical through-hole 450, according to an embodiment of the inventive concept. Referring to FIGS. 6A through 6D, the portions of the cover insulating layer 20, the interlayer insulating layer 200, the semiconductor layer 10, and the first filling insulating layer 400 that are cut to separate the semiconductor diodes D individually are filled by the second filling insulating layer 500. An upper surface of the second filling insulating layer 500 and an upper surface of the first filling insulating layer 400 may lie on substantially the same plane. Then, the vertical through-hole 450 is formed through the first filling insulating layer 400 and exposes the substrate 1. A side surface of the vertical through-hole 450 may expose a portion of the second impurity region 18 included in each of the semiconductor diode D. In this regard, instead of the second variable resistance material layer R2 illustrated in FIG. 4B, a third variable resistance material layer (not shown) may be formed on the surface of the second impurity region 18 that is exposed by the vertical through-hole 450. Even in this case, either the first variable resistance material layer R1 illustrated in FIG. 4A or the third variable resistance material layer may be selectively formed.

FIG. 6E is a sectional view for explaining a process of forming a vertical conductive layer, according to an embodiment of the inventive concept. Referring to FIGS. 6C and 6E, the vertical through-hole 450 is filled with a conductive material to form a vertical conductive layer 600 having a cylinder-shape. The vertical conductive layer 600 may electrically connect the second impurity regions 18 of the semiconductor diodes D along the third direction Z perpendicular to the surface of the substrate 1. Accordingly, the vertical conductive layer 600 may function as a bit line in the three-dimensional array of semiconductor diodes D.

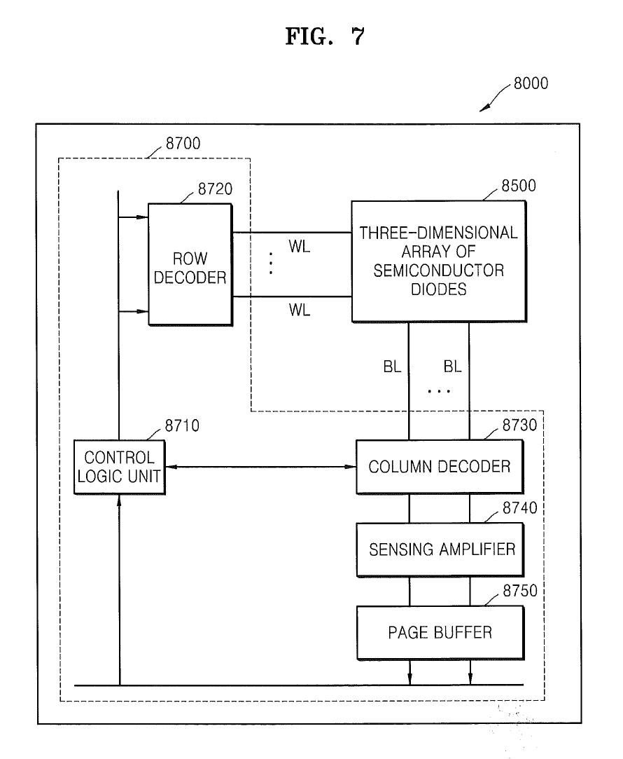

FIG. 7 is a schematic block diagram of a non-volatile memory device 8000 according to an embodiment of the inventive concept. Referring to FIG. 7, in the non-volatile memory device 8000, a three-dimensional array of semiconductor diodes 8500 may be combined with a core circuit unit 8700. For example, the three-dimensional array of semiconductor diodes 8500 may include any one of the three-dimensional arrays of semiconductor diodes D described in connection with FIGS. 4A through 5E. The core circuit unit 8700 may include a control logic unit 8710, a row decoder 8720, a column decoder 8730, a sensing amplifier 8740, and a page buffer 8750.

The control logic unit 8710 may communicate with the row decoder 8720, the column decoder 8730, and the page buffer 8750. The row decoder 8720 may communicate with the three-dimensional array of semiconductor diodes 8500 through a plurality of word lines WL. The column decoder 8730 may communicate with the three-dimensional array of semiconductor diodes 8500 through a plurality of bit lines BL. When the three-dimensional array of semiconductor diodes 8500 outputs signals, the sensing amplifier 8740 may be connected to the column decoder 8730, and when the three-dimensional array of semiconductor diodes 8500 receives signals, the sensing amplifier 8740 may not be connected to the column decoder 8730.

For example, the control logic unit 8710 may transmit a low address signal to the row decoder 8720, and the row decoder 8720 may decode the low address signal and may transmit the low address signal to the three-dimensional array of semiconductor diodes 8500 through a word line WL. The control logic unit 8710 may transmit a column address signal to the column decoder 8730 or the page buffer 8750, and the column decoder 8730 may decode the column address signal and may transmit the column address signal to the three-dimensional array of semiconductor diodes 8500 through a plurality of bit lines BL. The three-dimensional array of semiconductor diodes 8500 may transmit a signal to the sensing amplifier 8740 through the column decoder 8730, and the signal may be amplified in the sensing amplifier 8740 and transmitted to the control logic unit 8710 through the page buffer 8750.

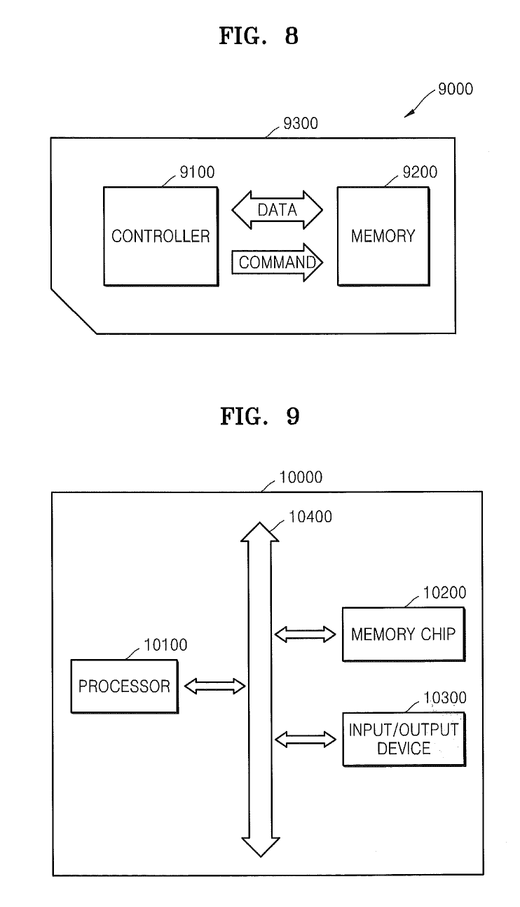

FIG. 8 is a schematic diagram of a memory card 9000 according to an embodiment of the inventive concept. Referring to FIG. 8, the memory card 9000 may include a controller 9100 and a memory 9200 which are included in a housing 9300. The controller 9100 may exchange an electrical signal with the memory 9200. For example, according to a command of the controller 9100, the memory 9200 and the controller 9100 may exchange data. Correspondingly, the memory card 9000 may store data in the memory 9200 or may output data stored in the memory 9200 to the outside. For example, the memory 9200 may include any one of the three-dimensional arrays of semiconductor diodes D described in connection with FIGS. 5A through 6E. The memory card 9000 may be used as a data storage medium for various portable devices. For example, the memory card 9000 may be a multi media card (MMC) or a secure digital card (SD).

FIG. 9 is a block diagram of an electronic system 10000 according to an embodiment of the inventive concept. Referring to FIG. 9, the electronic system 10000 may include a processor 10100, an input/output device 10300, and a memory chip 10200, which communicate data to each other through a bus 10400. The processor 10100 executes programs and controls the electronic system 10000. The input/output device 10300 may be used for inputting or outputting data of the electronic system 10000. The electronic system 10000 may be connected to an external device, such as a personal computer (PC) or a network, by using the input/output device 10300 and may communicate data to the external device. The memory chip 10200 may store a code or data for operating the processor 10100. For example, the memory chip 10200 may include any one of the three-dimensional arrays of semiconductor diodes D described in connection with FIGS. 5A through 6E.

The electronic system 10000 may be any one of various electronic control devices that require the memory chip 10200, and examples of the electronic system 10000 are a mobile phone, a MP3 player, a navigation device, a solid state disk (SSD), and household appliances.

While the inventive concept has been particularly shown and described with reference to exemplary embodiments thereof, it will be understood that various changes in form and details may be made therein without departing from the spirit and scope of the following claims.

1.-5. (canceled)

6. A method of forming a non-volatile memory device, comprising:
selectively implanting first conductivity type dopants into a semiconductor layer to thereby define a first impurity region therein having N-type or P-type conductivity;
selectively etching the first impurity region to define a sidewall thereon;
forming a first word line or a first bit line of the non-volatile memory device on the sidewall of the first impurity region; and
converting the semiconductor layer into a plurality of memory cells comprising respective portions of the first impurity region therein.

7. The method of claim 6, wherein said converting comprises:
selectively patterning the semiconductor layer into a plurality of memory cell active regions; and
incorporating second conductivity type dopants into each of the plurality of memory cell active regions to thereby define respective second impurity regions therein.

8. The method of claim 7, further comprising forming a second word line or second bit line on a corresponding first one of the second impurity regions.

9. The method of claim 8, further comprising forming a variable-resistance material sandwiched between the second word line or second bit line and the first one of the second impurity regions.

10. The method of claim 7, wherein said incorporating comprises incorporating second conductivity type dopants into a first of the plurality of memory cell active regions to thereby define a P-i-N diode therein.

11. The method of claim 7, further comprising forming a variable-resistance material sandwiched between the first word line or first bit line and the sidewall of the first impurity region.

12. A method of fabricating a non-volatile memory device, the method comprising:
forming a stack structure that comprises:
a plurality of horizontal device layers disposed spaced apart from each other at different levels in a third direction that is perpendicular to a surface of a substrate, wherein each of the horizontal device layers comprises:
a semiconductor layer comprising a first impurity region having a first conductivity type on one side of the semiconductor layer in a first direction parallel to the surface of the substrate; and
a horizontal conductive layer that is disposed near the one side of the semiconductor layer and extends in a second direction that is parallel to the surface of the substrate and is perpendicular to the first direction; and
an interlayer insulating layer interposed between neighboring horizontal device layers;
forming a second impurity region on the other side of the semiconductor layer comprised in each of the horizontal device layers opposite to the one side of the semiconductor layer in a direction opposite to the first direction by implanting an impurity having a second conductivity type that is different from the first conductivity type; and
forming a three-dimensional array of semiconductor diodes by dividing the semiconductor layer comprised in each of the horizontal device layers into pluralities in a direction from the one side of the semiconductor layer to the other side of the semiconductor layer and each of the semiconductor diodes comprises a portion of the first impurity region and a portion of the second impurity region.

13. The method of claim 12, further comprising:
after the forming of the three-dimensional array of semiconductor diodes, forming vertical conductive layers that extend in the third direction on the substrate and are electrically connected to the portions of the second impurity region comprised in each of the semiconductor diodes aligned in the third direction in the three-dimensional array of semiconductor diodes, respectively.

14. The method of claim 13, further comprising, after the forming of the second impurity region, forming a vertical filler conductive layer that contacts the second impurity region of the semiconductor layer comprised in each of the horizontal device layers; wherein, in the forming of the vertical conductive layer, the vertical conductive layer is formed by dividing the vertical filler conductive layer along a extending line passing through the sides of the semiconductor layer.

15. The method of claim 12, wherein, in the forming of the stack structure, the horizontal device layers and the interlayer insulating layer are alternately formed such that an interlayer insulating layer is interposed between neighboring horizontal device layers.

16. The method of claim 12, wherein, in the forming of the stack structure, each of the horizontal device layers further comprises a cover insulating layer and a spacer layer formed on the semiconductor layer, wherein the spacer layer covers an upper surface of the first impurity region and the cover insulating layer covers an upper surface of a portion of the semiconductor layer other than the first impurity region.

17. The method of claim 16, wherein an upper surface of the horizontal conductive layer and an upper surface of the cover insulating layer lie on the same plane.

18. The method of claim 16, wherein the forming of the second impurity region comprises:
removing a portion of the stack structure to expose a side surface of the semiconductor layer on the other side of the semiconductor layer and the substrate;
laterally recessing portions of the cover insulating layer and the interlayer insulating layer to protrude a portion of the semiconductor layer on the other side of the semiconductor layer; and
implanting the impurity having the second conductivity type in the protruding portion of the semiconductor layer.

19. The method of claim 12, wherein, in the forming of the stack structure, the horizontal device layer is formed by:
forming a semiconductor layer that comprises a preliminary first impurity region having the first conductivity type and a cover insulating layer that covers the semiconductor layer and has an opening exposing the preliminary first impurity region on the substrate;
forming a spacer layer contacting a side surface of the cover insulating layer in the opening;
forming a trench passing through the semiconductor layer and the first impurity region by anisotropic etching the cover insulating layer and the spacer layer as an etch mask; and
forming the horizontal conductive layer by filling the trench with a conductive material.

20. The method of claim 19, wherein the forming of the semiconductor layer and the cover insulating layer comprises:
forming the semiconductor layer on the substrate;
forming the cover insulating layer covering the semiconductor layer;
forming an opening in the cover insulating layer to expose the semiconductor layer; and
forming the preliminary first impurity region by implanting the first impurity having the first conductivity type in a portion of the semiconductor layer through the opening.

21. The method of claim 19, further comprising, between the forming of the trench and the first impurity region and the forming of the horizontal conductive layer, forming a variable resistance material layer on a portion of the first impurity region that is exposed in the trench.

22. The method of claim 13, further comprising, before the forming of the vertical conductive layer, forming a variable resistance material layer between the second impurity region and the vertical conductive layer.

23.-28. (canceled)

29. A method of fabricating a non-volatile memory device, the method comprising:
forming a stack structure that comprises:
a plurality of horizontal device layers disposed spaced apart from each other at different levels in a third direction that is perpendicular to a surface of a substrate, wherein each of the horizontal device layers comprises:
a semiconductor layer comprising a first impurity region having a first conductivity type on one side of the semiconductor layer in a first direction parallel to the surface of the substrate,
a spacer layer covering an upper surface of the first impurity region,
a cover insulating layer covering an upper surface of a portion of the semiconductor layer other than the first impurity region,
a horizontal conductive layer that extends in a second direction that is parallel to the surface of the substrate and is perpendicular to the first direction, and
a variable resistance material layer interposed between the first impurity region and the horizontal conductive layer; and
an interlayer insulating layer interposed between neighboring horizontal device layers;
forming a second impurity region on the other side of the semiconductor layer comprised in each of the horizontal device layers opposite to the one side of the semiconductor layer in a direction opposite to the first direction by implanting an impurity having a second conductivity type that is different from the first conductivity type; and
forming a three-dimensional array of semiconductor diodes by dividing the semiconductor layer comprised in each of the horizontal device layers into pluralities in a direction from the one side of the semiconductor layer to the other side of the semiconductor layer and each of the semiconductor diodes comprises a portion of the first impurity region and a portion of the second impurity region.

30. The method of claim 29, further comprising, after the forming of the three-dimensional array of semiconductor diodes, forming a pillar-shape vertical conductive layer that extends in the third direction perpendicular to the surface of the substrate and that is electrically connected to a portion of the second impurity region comprised in each of the semiconductor diodes aligned in the third direction perpendicular to the surface of the substrate in the three-dimensional array of semiconductor diodes, respectively.

31. The method of claim 29, wherein the semiconductor diode has a p-i-n structure.
